(19) United States
(12) Patent Application Publication
(10) Pub. No.: US 2008/0142968 A1
(43) Pub. Date: Jun. 19, 2008

(54) STRUCTURE FOR CONTROLLED COLLAPSE CHIP CONNECTION WITH A CAPTURED PAD GEOMETRY

(75) Inventors: Virendra R. Jadhav, Wappingers Falls, NY (US); Scott P. Moore, Apalachin, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/611,464

(22) Filed: Dec. 15, 2006

(51) Int. Cl. H01L 23/488; H01L 21/44

(52) U.S. Cl. 257/738; 438/613; 257/E21.476; 257/E23.023

(57) ABSTRACT

A structure for controlled collapse chip connection disposed above a substrate. The substrate has two faces, with the second face being disposed substantially parallel to the first face. A contact pad in signal communication with the integrated circuit is disposed on the second face. A first passivation layer forms a first angled aperture substantially above the contact pad. The angled aperture increasing in circumference with increasing distance from the contact pad. A ball-limiting metallurgy (BLM) disposed within the aperture, with a center section in signal communication with the contact pad, an angled section extending away from the center portion and terminated in an edge section. A second passivation layer disposed on the first passivation layer, and partially encapsulating the edge region of the BLM with a second angled aperture. The shape and slope of the BLM and the second angled aperture controls the formation of a solder ball.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates generally to controlled collapse chip connection, and more particularly to providing a structure and method for an enhanced ball limiting metallurgy with a captured pad geometry.

2. Description of the Background

Controlled-Collapse Chip Connection (C4) is a means of connecting IC (integrated circuit) chips to substrates in electronic packages. C4 is known as a flip-chip technology, in which the interconnections are small solder balls on the bottom side chip surface. C4 technology represents one of the highest density schemes known in the art for chip interconnections. The C4 technology was initially developed in the 1960s and has proven reliable in the semiconductor field. Historically, the PbSn solder for the formation of the solder ball was evaporated through a metal mask. In the 1990s, electrochemical fabrication of C4 interconnections was introduced. Electroplating is more extendible than evaporation to small C4-pad dimensions, closer pad spacing, larger wafers, and lower-melting solders (which have a higher content of Sn).

In general, the top layers of an integrated circuit (IC) chip are wiring levels, separated by insulating layers of dielectric material that provide input/output for the device. In C4 structures, the chip wiring is terminated by a plurality of metal films that form the ball-limiting metallurgy (BLM), which is also referred to as under-bump metallurgy (UBM). The ball-limiting metallurgy defines the size of the solder bump after reflow, provides a surface that is wettable by the solder, and that reacts with the solder to provide good adhesion and acceptable reliability under mechanical and heat stress. The BLM also serves as a barrier between the integrated-circuit device and the metals in the interconnection.

FIGS. 1A and 1B are a typical implementation of the C4 manufacturing process. In FIG. 1A an IC 100 formed on a base material 102 (for example, silicon) has a solder ball 108 formed for subsequent attachment to a contact pad 112 (see FIG. 1B) on a carrier 114. A BLM 106 constricts the solder flow and aids in the formation of the solder ball 108 (which is formed by reflowing a deposit of solder paste), and serves as a wettable surface and contact for an underlying contact 110 for the IC 100. A passivation layer 104, typically a polymer dielectric, insulates the IC 100, and supports the BLM 106. In FIG. 1B the IC 100 is attached to the contact pad 112 on the carrier 114, by reflowing the solder ball 108. Solder flow is restricted on the carrier 114 by solder dams 116, which outline and define the contact pad 112. A secondary reflow is employed to attach the IC 100 to the contact pad 112 on the carrier 114.

However, despite the widespread use of C4 technology, the current solder bump and BLM dimensions have resulted in cracking and metal layer separation at the chip level after attachment to a carrier. It is typical to match pad diameter (area) on the chip to the target carrier pad. An increase in the BLM size results in a matching increase of the carrier pad, and leads to reduction of wireability on the carrier. Solder undercut of the BLM, essentially acts to reduce the pad diameter, and contributes to increasing stress at the joint. The disadvantages of the prior C4 implementations of FIG. 1A and FIG. 1B arise in the realization the BLM and passivation layer geometries.

### SUMMARY OF THE INVENTION

Embodiments of the present invention comprise a structure for controlled collapse chip connection disposed above a substrate. The substrate is configured for integrated circuit formation therein. A contact pad in signal communication with the integrated circuit is disposed on the upper surface of the substrate. A first passivation layer, with a bottom and top surface, is disposed on the upper surface of the substrate. The bottom surface is substantially parallel to the top surface, and the bottom surface is in contact with the upper surface of the substrate. The first passivation layer forms a first angled aperture substantially above the contact pad, with the first angled aperture increasing in circumference with increasing distance from the contact pad. A ball-limiting metallurgy (BLM) is disposed within the aperture. The BLM comprises a center section substantially in parallel to and in signal communication with the contact pad, an angled section extending away from the center portion and terminated in an edge section. The angled section is substantially parallel to and in contact with the first angled aperture. The edge section is substantially parallel to the top surface. A second passivation layer disposed on the first passivation layer, and partially encapsulating the edge region of the BLM with a second angled aperture. The shape and slope of said BLM and the second angled aperture controls the formation of a solder ball.

A method for formation of a controlled collapse chip connection disposed above a substrate with a contact pad is also provided. The method comprises disposing a first passivation layer with a bottom and top surface on the substrate. The bottom surface substantially parallel to the top surface, and the bottom surface in contact with the side of the substrate with the contact pad. The first passivation layer forms a first angled aperture substantially above the contact pad. The first angled aperture increasing in circumference with increasing distance from the contact pad. Forming a ball-limiting metallurgy (BLM) and disposing the BLM within the first angled aperture. The BLM comprises a center section substantially in parallel to and in signal communication with the contact pad, an angled section extending away from the center portion and terminated in an edge section. The angled section is substantially parallel to and in contact with the first angled aperture. The edge section is substantially parallel to the top surface. Disposing a second passivation layer on the first passivation layer, and partially encapsulating the edge region of the BLM with a second angled aperture. Controlling the shape and slope of the BLM and the second angled aperture in order to influence the development and formation of a solder ball.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, a solution is technically achieved in which solder attach between an IC chip and a carrier employing controlled-collapse chip connection (C4) is enhanced by a captured pad geometry. The captured pad geometry is realized with a second passivation layer that encapsulates the ball limiting metallurgy (BLM). The second passivation layer has the effect of narrowing the area of the BLM that contacts the solder ball. The encapsulation of the BLM leads to several advantages such as reducing the effect of any solder undercut of the ball limiting metallurgy, and improved anchoring of the BLM to the IC chip. Furthermore, by narrowing the contact area of the solder ball, the height of the solder ball is increased which reduces mechanical stress on the chip interconnection.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A is a cross sectional view of a solder ball formed on ball limiting metallurgy attached to an integrated circuit.

FIG. 1B is a cross sectional view of an integrated circuit joined to a carrier employing controlled-collapse chip connection (C4).

FIG. 2 is a cross sectional view of an integrated circuit joined to a carrier employing the captured pad geometry according to an embodiment of the present invention.

The detailed description explains the preferred embodiments of the invention, together with advantages and features, by way of example with reference to the drawings.

### DETAILED DESCRIPTION OF SPECIFIC EMBODIMENTS

Embodiments of the present invention provide a structure and method for solder attach between an IC chip and a carrier employing controlled-collapse chip connection (C4) that is enhanced by a captured pad geometry. The captured pad geometry is realized with a second passivation layer that encapsulates the ball limiting metallurgy (BLM). The second passivation layer has the effect of narrowing the area of the BLM that contacts the solder ball. The encapsulation of the BLM leads to several advantages such as reducing the effect of any solder undercut of the ball limiting metallurgy, and improved anchoring of the BLM to the IC chip. Furthermore, by narrowing the contact area of the solder ball, the height of the solder ball is increased which reduces mechanical stress on the chip interconnection.

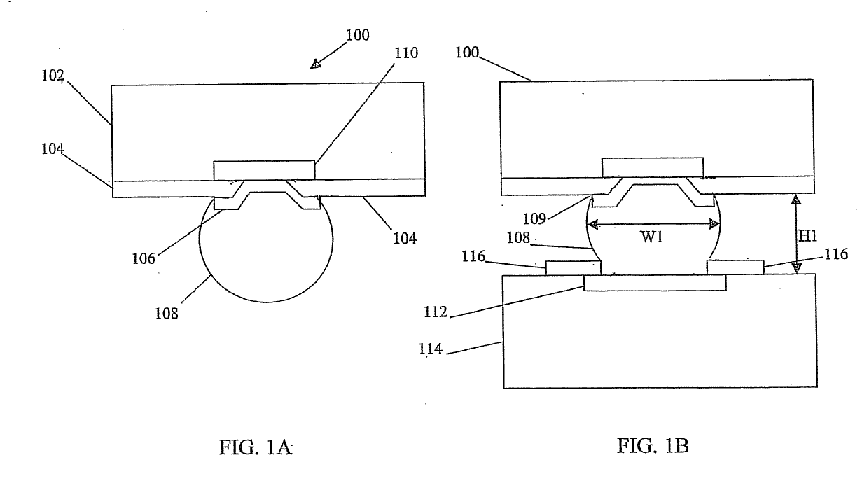

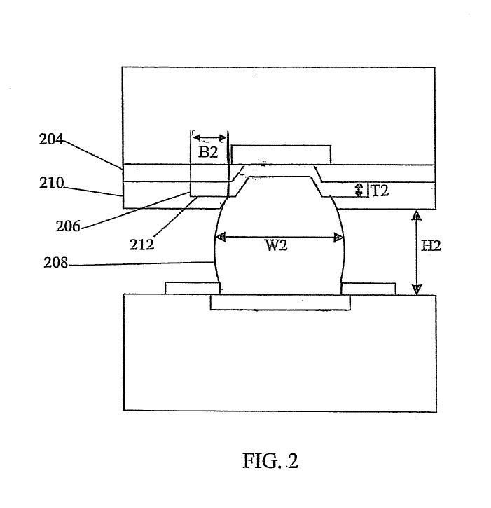

The captured pad geometry embodied in the present invention facilitates a larger metal pad on the chip side of a C4 connection, which helps to spread the stress caused by the interconnection of the chip to a higher CTE (coefficient of thermal expansion) carrier. The captured pad structure is created by a second layer of polymer dielectric (for example, photosensitive polyimide (PSPI)) being applied over the edge areas of the BLM pad metal. The captured pad structure reinforces the edge of the BLM pad, and helps to anchor the BLM to the chip surface. The additional polymer dielectric eliminates the potential of solder from undercutting the BLM (see 109 in FIG. 1B). The captured pad geometry results in a higher chip to carrier standoff post assembly (H2 greater than H1, see FIG. 1B and FIG. 2, with W1 greater than W2) with the same solder volume given the reduction in effective BLM solderable area. The increased standoff reduces joint stress by further decoupling the chip from the carrier.

FIG. 2 depicts the captured pad geometry of the present invention. A first layer of polymer dielectric 204 is deposited over the carrier and supports the BLM 206. In some embodiments of the present invention the edge region 212 of the BLM 206 can be extended in length, as is the case in FIG. 2 in relation to FIGS. 1A and 1B. A second layer of polymer dielectric 210 partially encapsulates the edge region 212 of the BLM 206 and provides the captured pad geometry. As previously explained, the solder ball 208 has a reduced width (W2) and elongates (H2) for a given solder volume versus the non-captured pad design (as shown in FIG. 1B). The reason for the reduced width (W2) is because the second layer of polymer dielectric covers portions of the edge region 212 of the BLM 206 thereby restricting the wettable area, as well as constricting the solder flow on the chip The reduction in the width of the solder ball 208, allows for a reduction in the pad size on the carrier, which potentially increases carrier wireability.

An exemplary method for creating the captured pad geometry of an embodiment of the present invention is as follows. Create the BLM pad with the first passivation layer (for example, PSPI) via structure. Etch seed layer needed for plating the BLM layers. Prepare the exposed PSPI surface for subsequent PSPI layer deposition (mild etch, possibly Potassium Permaganate with a mild acid rinse). Develop vias in the PSPI overcoat (second passivation layer) to the larger BLM pad. Maintain wall angles (for example, 45 degrees, via top larger than via bottom) on the via side walls such that stress concentrations are not developed. This structure and process is more directly applicable to C4NP (C4 new process) type solder deposition, where a seed layer is not required for creating the solder deposit. Plated solder deposition processes would require that a communing layer be deposited after the captured pad structure is created to allow solder plating with subsequent etching being required.

In exemplary embodiments of the present invention the draft angle on the via and captured pad walls is maintained between about 40 to about 75 degrees, with the thickness (T2) of the edge region 212 of the BLM 206 being maintained between about 6 um to about 40 um, with the minimum length (B2) of the edge region 212 being at least 3 times its thickness (T2), resulting in the height (H2) of the solder ball 208 greater than the width (W2). Additionally, in exemplary embodiments the chip/carrier solder pad areas are maintained within about +/−25 percent of each other.

An example of existing dimensions for 3on6 (3 mil diameter solder bump with 6 mil spacing between bumps) attachment to ball grid array (BGA) carrier is as follows. A BLM with a 4 um thickness and an overall attachment width of 85 um, of which 47 um is in the lower center section of the BLM that is in contact with the underlying contact pad of the chip. The BLM rises from the lower center section at a 65 degree angle, and partially covers a 3 um thick PSPI passivation layer by about 19 um (edge section) on each side. When a solder bump with an initial volume of 36.76×10⁴ um³ is employed with the aforementioned chip dimensions is attached to a contact pad with a 70 um solder resist opening (SRO), the resultant joint height is about 60 um (as measured from contact pad surface to the exposed surface of the PSPI), and the solder bumps maximum width is about 95 um.

For the same solder volume and SRO on the contact surface as the aforementioned case, where an embodiment of the present invention is employed for 3 on6 technology the following has been observed. An additional 6 um of PSPI forms a second layer (with an aperture wall at a 65 angle) that acts to partially encapsulate the BLM edge sections (that have been increased in length to 24 um from 19 um) and cover the initial 3 um of PSPI, with a resultant reduction of the attachment width from 85 um to 70 um. With the captured pad geometry, the resultant joint height is about 60.8 um, and the solder bump maximum width is 75.6 um.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A structure for controlled collapse chip connection disposed above a substrate comprising:
a substrate configured for integrated circuit formation therein;
a contact pad disposed on an upper surface of the substrate;
a first passivation layer atop said contact pad;
wherein said first passivation layer forms a first angled aperture substantially above said contact pad, said first angled aperture increasing in circumference with increasing distance from said contact pad;
a ball-limiting metallurgy (BLM) disposed within said first angled aperture;
wherein said BLM comprises a center section substantially in parallel to and in signal communication with said contact pad, an angled section extending away from said center portion and terminated in an edge section;
wherein said angled section is substantially parallel to and in contact with said first angled aperture;
wherein said edge section is substantially parallel to said top surface;
a second passivation layer disposed on said first passivation layer, and partially encapsulating the edge region of said BLM so as to define a second angled aperture; and
wherein the shape and slope of said BLM and said second angled aperture controls the formation of a solder ball.

2. The structure of claim 1 wherein said first and second passivation layer are a polymer dielectric.

3. The structure of claim 1 wherein said first and said second passivation layer are formed from photosensitive polyimide.

4. The structure of claim 1 wherein said second passivation layer narrows the area of said BLM that contacts said solder ball; and
wherein during chip connection to a target carrier the resultant separation (H2) between said chip and said target carrier is increased by the constricting action of said second passivation layer on said solder ball; and
wherein the constricting action reduces the width (W2) of said solder ball to maintain H2 greater than W2.

5. The structure of claim 4 wherein said increased separation (H2) between said chip and said target carrier reduces the mechanical stress on the chip interconnection.

6. The structure of claim 1 wherein the edge section of said BLM has a thickness (T2) of about 6 um to about 40 um.

7. The structure of claim 6 wherein the edge section of said BLM has a minimum length (B2) of about 3 times the thickness (T2).

8. The structure of claim 1 wherein the angled section of said BLM and of said second angled aperture is between about 40 to about 75 degrees

9. The structure of claim 1 wherein said partial encapsulation of said BLM prevents solder undercut of the BLM.

10. The structure of claim 1 wherein said partial encapsulation of said BLM strengthens the mechanical connection between said BLM and said substrate.

11. The structure of claim 1 wherein the BLM serves as a solder wettable surface, that reacts with said solder to provide a mechanical connection.

12. The structure of claim 1 wherein connection pads on a carrier are maintained within about plus or minus 25 percent of the solder wettable area of the BLM.

13. The structure of claim 1 wherein the BLM serves as a barrier between said contact pad and the metals of a solder interconnection.

14. The structure of claim 1 wherein said edge sections can be increased to strengthen the mechanical connection of said BLM to said substrate.

15. A method for formation of a controlled collapse chip connection disposed above a substrate, the method comprising:
forming a substrate configured for integrated circuit formation therein, the substrate having a first and a second face, the second face being disposed substantially parallel to the first face;
forming a contact pad in signal communication with the integrated circuit, the contact pad disposed on the second face;
disposing a first passivation layer with a bottom and top surface on the second face, the bottom surface substantially parallel to the top surface, and the bottom surface in contact with the second face; and
wherein the first passivation layer forms a first angled aperture substantially above the contact pad, the first angled aperture increasing in circumference with increasing distance from the contact pad;
forming a ball-limiting metallurgy (BLM) and disposing the BLM within the first angled aperture;
wherein the BLM comprises a center section substantially in parallel to and in signal communication with the contact pad, an angled section extending away from the center portion and terminated in an edge section;
wherein the angled section is substantially parallel to and in contact with the first angled aperture;
wherein the edge section is substantially parallel to the top surface;
disposing a second passivation layer on the first passivation layer, and partially encapsulating the edge region of the BLM with a second angled aperture; and
controlling the shape and slope of the BLM and the second angled aperture in order to influence the development and formation of a solder ball.

16. A method for formation of a controlled collapse chip connection disposed above a substrate with a contact pad, the method comprising:
disposing a first passivation layer with a bottom and top surface on the substrate, the bottom surface substantially parallel to the top surface, and the bottom surface in contact with the side of the substrate with the contact pad; and
wherein the first passivation layer forms a first angled aperture substantially above the contact pad, the first angled aperture increasing in circumference with increasing distance from the contact pad;
forming a ball-limiting metallurgy (BLM) and disposing the BLM within the first angled aperture;
wherein the BLM comprises a center section substantially in parallel to and in signal communication with the contact pad, an angled section extending away from the center portion and terminated in an edge section;
wherein the angled section is substantially parallel to and in contact with the first angled aperture;
wherein the edge section is substantially parallel to the top surface;
disposing a second passivation layer on the first passivation layer, and partially encapsulating the edge region of the BLM with a second angled aperture; and
controlling the shape and slope of the BLM and the second angled aperture in order to influence the development and formation of a solder ball.
